(19) United States
(12) Patent Application Publication
(10) Pub. No.: US 2023/0371196 A1
(43) Pub. Date: Nov. 16, 2023

(54) SYSTEM AND METHOD OF AUTOMATIC MONITORING OF RACK SPACE USAGE IN A DATA CENTRE

(71) Applicant: JIO PLATFORMS LIMITED, Ahmedabad (IN)

(72) Inventors: Deepak GUPTA, Maharashtra (IN); Atul AGRAWAL, Maharashtra (IN); Nekiram KHOSYA, Maharashtra (IN); Renuka NAIR, Maharashtra (IN)

(21) Appl. No.: 18/246,390

(22) PCT Filed: Jul. 27, 2022
(86) PCT No.: PCT/IB2022/056924

§ 371 Date: Mar. 23, 2023

(30) Foreign Application Priority Data
Jul. 29, 2021 (IN) 202121034198

(51) Int. Cl. H05K 7/14; H05K 7/18; G01S 17/04

(52) U.S. Cl. CPC H05K 7/1498; H05K 7/18; G01S 17/04

(57) ABSTRACT

The present invention provides a robust and effective solution to an entity (114) or an organization by enabling them to implement a system (110) for facilitating monitoring of space available at each rack level in a data centre (108) through a plurality of IoT based wireless sensor monitoring devices (116) and a wireless network gateway device (120). This disclosure provides measuring space at each rack level and collating the rack space available at each rack level for a data centre infrastructure that will give a true picture of rack space efficiency in a data centre (108).

### FIELD OF INVENTION

The embodiments of the present disclosure generally relate to monitoring data centre assets. More particularly, the present disclosure relates to designing a sensor network to monitor rack space usage at each rack level in a data centre.

### BACKGROUND OF THE INVENTION

The following description of related art is intended to provide background information pertaining to the field of the disclosure. This section may include certain aspects of the art that may be related to various features of the present disclosure. However, it should be appreciated that this section be used only to enhance the understanding of the reader with respect to the present disclosure, and not as admissions of prior art.

Along with the growth of digital services and devices, the typical cloud data centre environment has grown. The storage systems today are often organized in data centres. Such data centres may contain hundreds or thousands of computers. There is a large collection of interconnected servers that provide computing and/or storage capacity to run various applications. A data centre may comprise a facility that hosts applications and services for subscribers, i.e., customers or users of data centre. The data centre may, for example, host all the infrastructure equipment, such as networking and storage systems, redundant power supplies, and environmental controls. In a typical data centre, clusters of storage systems and application servers are interconnected via high-speed switch fabric provided by one or more tiers of physical network switches and routers. More sophisticated data centres provide infrastructure spread throughout the globe with subscriber support equipment located in various physical hosting facilities. Many data centres today are dependent on the physical infrastructure of a particular data centre. A data centre can be modelled as rows of racks that house electronic systems, such as computing systems or other types of electrical devices. The computing systems (such as computers, storage devices, servers, routers, networking devices, etc.) consume power for their operation. The computing systems of the data centre may reside in these racks. In a typical data centre, there may be dozens or even hundreds of electrical devices.

To expand further, a data centre is a physical facility that organizations or entities use to house their critical applications and data. The key components of a data centre design include routers, switches, firewalls, storage systems, servers, and application-delivery controllers. Typically, in a data centre hundreds of racks are installed, power with megawatt capacity is provisioned and huge capacity of cooling infrastructure is provided. A huge amount of CAPEX is invested initially to build a data centre. While spending this huge CAPEX, it is worthy to use these resources at its maximum efficiency during its operations. And to know the usage of resources in data centre operations smart monitoring devices are required. To manage space in most efficient manner it is necessary to monitor few critical parameters—in each rack inside the data centre. Existing systems have many issues that create a chain of undesirable side effects such as equipment lying in the warehouse awaiting installation, uneconomical use of space creating a perception of scarcity, need for personal intervention to get ‘reserved’ space vacated and general lack of transparency. The issues are as follows:
Poor visibility on power utilization
Manual and incomplete data collection
No real time monitoring tools in Jio facilities
Management through Excel Work sheets

In recent years, as data centres have grown in size and complexity, the mapping tools that manage them must be able to effectively identify rack space while implementing appropriate policies. Traditionally, network administrators have to manually implement policies, manage mapping access control lists (MACLs), configure lists, map misconfigured or infected machines, diagnose the infected resources, identity rack space, etc. These tasks can become exponentially more complicated as a network grows in size and require an intimate knowledge of a large number of data centre components. Furthermore, misconfigured machines can shut down a data centre within minutes while it could take a network administrator hours or days to map and determine the root problem and provide a solution.

The existing data centres do not have the facility to measure rack space in a data centre. There has been a repetitive and time-consuming exercise whenever any new product or service is to be deployed as part of core infrastructure in the data centres and other facilities. There is no efficient and transparent management system to manage or monitor spaces of the racks in all facilities. As network expands and new sites are added, the efficient use of building space becomes even more critical. As of now, there is no tool available by which we can check space in real time in all facilities. At present everything is managed through excel worksheets and may not reflect the recent status.

There is, therefore, a need in the art to provide a system and a method that facilitates determination of rack space availability and monitor spaces in racks in a data centre by mitigating the limitations in the art. There is a need for a system that aims to monitor rack space usage at each rack level in a data centre through IoT based wireless sensor devices. Measuring this data at each rack level and collating it for a data centre infrastructure will give a true picture of rack space efficiency usage in data centre.

### OBJECTS OF THE PRESENT DISCLOSURE

Some of the objects of the present disclosure, which at least one embodiment herein satisfies are as listed herein below.

It is an object of the present disclosure to provide a system and a method to facilitate monitoring of rack space in a data centre for large facilities.

It is an object of the present disclosure to provide a system to mitigate the current four key pain-points which contribute to unnecessary delays in project execution running into months and even quarters.

It is an object of the present disclosure to provide a system and a method to monitor space usage at each rack level in a data centre.

It is an object of the present disclosure to provide a system and a method for collating data measurements in each rack level in a data centre infrastructure to give a true picture of the data centre efficiency.

It is an object of the present disclosure to provide a system that eliminates a huge number of cables and wires.

### SUMMARY

This section is provided to introduce certain objects and aspects of the present disclosure in a simplified form that are further described below in the detailed description. This summary is not intended to identify the key features or the scope of the claimed subject matter.

In an aspect, the present disclosure provides for a system for facilitating rack space measurement of a data centre of an entity. The system may include a wireless sensor monitoring device operatively coupled to a processor through a network. In an embodiment, the wireless sensor monitoring device may include a plurality of sensors operatively coupled to a plurality of racks of the data centre. The plurality of racks may have a plurality of computing devices residing in each rack. In an embodiment, the plurality of sensors may be configured to transmit an infrared signal (IR) to each rack. In an embodiment, the processor may be coupled with a memory that may store instructions which when executed by the processor causes the processor to receive a first set of signals from the wireless sensor monitoring device pertaining to one or more reflected infrared signals reflected from each rack. The one or more reflected signals may be obtained after reflection of an IR signal from each rack. The IR signal may be transmitted by the plurality of sensors. The processor may extract a first set of attributes from the first set of signals pertaining to information present in the one or more reflected IR signals and determine, based on extracted first set of attributes, a number of computing devices residing in the rack. The processor may further correlate the number of computing devices with a maximum capacity of computing devices in the rack and, thereby determine based on the correlated number of computing devices, an amount of space available in the rack.

In an embodiment, the processor may collate the first set of attributes for the plurality of racks to determine a total space availability in the data centre.

In an embodiment, the plurality of sensors may be a plurality of IR sensors placed in a predefined position in each rack, and each IR sensor may include an IR transmitter and an IR receiver. In an embodiment, the IR transmitter may be configured to transmit an IR signal to a rack and the IR receiver may be configured to receive a reflected IR signal from the rack.

In an embodiment, each IR sensor may be of a predetermined size placed at a predefined distance from each other based on a length of each rack in the data centre.

In an embodiment, the wireless sensor monitoring device further comprises a plurality of microcontroller units (MCU) and a plurality of buffer units operatively coupled to each IR sensor.

In an embodiment, a centralized server may be operatively coupled to the system and store the first set of signals, the first set of attributes, the second set of attributes, total space availability in the data centre and total number of computing devices in each rack in the data centre.

In an embodiment, a user device may be communicably coupled to the centralized server through the network. The user device may enable a user to store, access and monitor the centralized server remotely through the network.

In an aspect, the present disclosure provides for a wireless gateway device for collecting rack space measurement data of a data centre of an entity. The device may include an antenna unit, a local area network (LAN) and a processor. The antenna unit may be configured to collect an amount of space availability in the rack determined by the system. The LAN may be further operatively coupled to a centralized server through a network and the processor may be coupled with a memory that may store instructions which when executed by the processor causes the processor to receive the amount of space availability in the rack determined by the system and then transmit the received amount of space availability in the rack to the centralized server.

In an embodiment, the wireless gateway device may be of a predetermined size that do not require any rack space.

In an embodiment, the device may be further configured to manage a plurality of systems.

In an aspect, the present disclosure provides a method for facilitating rack space measurement of a data centre of an entity. The method may include the step of receiving, by a processor, a first set of signals from a wireless sensor monitoring device pertaining to one or more reflected infrared signals reflected from each said rack. The one or more reflected signals may be obtained after reflection of an IR signal from each rack, where the IR signal may be transmitted by the plurality of sensors. In an embodiment, the wireless sensor monitoring device comprising a plurality of sensors operatively coupled to a plurality of racks of the data centre. The plurality of racks having a plurality of computing devices residing in each rack, and the plurality of sensors may be configured to transmit an infrared signal (IR) to each rack. In an embodiment, the wireless sensor monitoring device may be operatively coupled to the processor coupled with a memory storing instructions that are executed by the processor. The method may include the step of extracting, by the processor, a first set of attributes from the first set of signals, the first set of attributes pertaining to information present in the one or more reflected IR signals and then the step of determining, by the processor, based on extracted first set of attributes, a number of computing devices residing in the rack. Further, the method may include the step of correlating, by the processor, the number of computing devices with a maximum capacity of number of computing devices in the rack; and then the step of determining, by the processor, based on the correlated number of computing devices, a space available in the rack.

Thus, the above embodiments clearly help in meeting the objectives of monitoring of rack space in a data centre for large facilities, mitigating key pain-points which contribute to unnecessary delays in project execution running into months and even quarters, monitoring space usage at each rack level in a data centre, collating data measurements in each rack level in a data centre infrastructure to give a true picture of the data centre efficiency and eliminating a huge amount of cables and wires as the system is wirelessly connected to the sensors.

### BRIEF DESCRIPTION OF DRAWINGS

The accompanying drawings, which are incorporated herein, and constitute a part of this invention, illustrate exemplary embodiments of the disclosed methods and systems in which like reference numerals refer to the same parts throughout the different drawings. Components in the drawings are not necessarily to scale, emphasis instead being placed upon clearly illustrating the principles of the present invention. Some drawings may indicate the components using block diagrams and may not represent the internal circuitry of each component. It will be appreciated by those skilled in the art that invention of such drawings includes the invention of electrical components, electronic components or circuitry commonly used to implement such components.

FIG. 1A illustrates an exemplary network architecture in which or with which the system (110) of the present disclosure can be implemented, in accordance with an embodiment of the present disclosure.

FIG. 1B illustrates an exemplary network architecture of a wireless network gateway device (120) of the present disclosure can be implemented, in accordance with an embodiment of the present disclosure.

FIG. 2A illustrates an exemplary representation (200) of the system (110), in accordance with an embodiment of the present disclosure.

FIG. 2B illustrates an exemplary representation (250) of the wireless network gateway device (120), in accordance with an embodiment of the present disclosure.

FIG. 3 illustrates exemplary method flow diagram (300) depicting a method for facilitating rack space availability, in accordance with an embodiment of the present disclosure.

FIGS. 4A-4D illustrate exemplary representations of a Functional Block Diagram of a rack space sensor (400) and its implementation, in accordance with an embodiment of the present disclosure.

FIG. 5 illustrates an exemplary representation (500) of a flow diagram for rack space measurement method, in accordance with an embodiment of the present disclosure.

FIGS. 6A-6B illustrate exemplary representations (600) of a Functional Block diagram of wireless network gateway device and its implementation, in accordance with an embodiment of the present disclosure.

FIG. 7 illustrates an exemplary representation (700) of a flow diagram of data flow from the rack sensor to cloud, in accordance with an embodiment of the present disclosure.

FIG. 8 illustrates an exemplary computer system in which or with which embodiments of the present invention can be utilized in accordance with embodiments of the present disclosure.

The foregoing shall be more apparent from the following more detailed description of the invention.

### BRIEF DESCRIPTION OF INVENTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The present invention provides a robust and effective solution to an entity or an organization by enabling them to implement a system for facilitating monitoring of data usage at each rack level in a data centre to determine rack space availability through IoT based wireless sensor devices. By measuring space usage at each rack level and collating those for a data centre infrastructure will give a true picture of data centre efficiency.

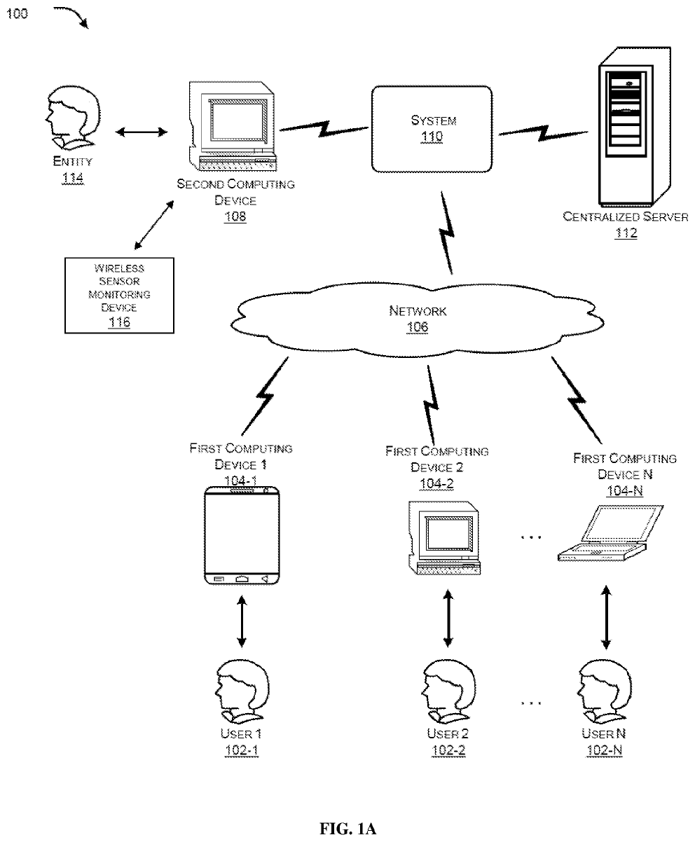

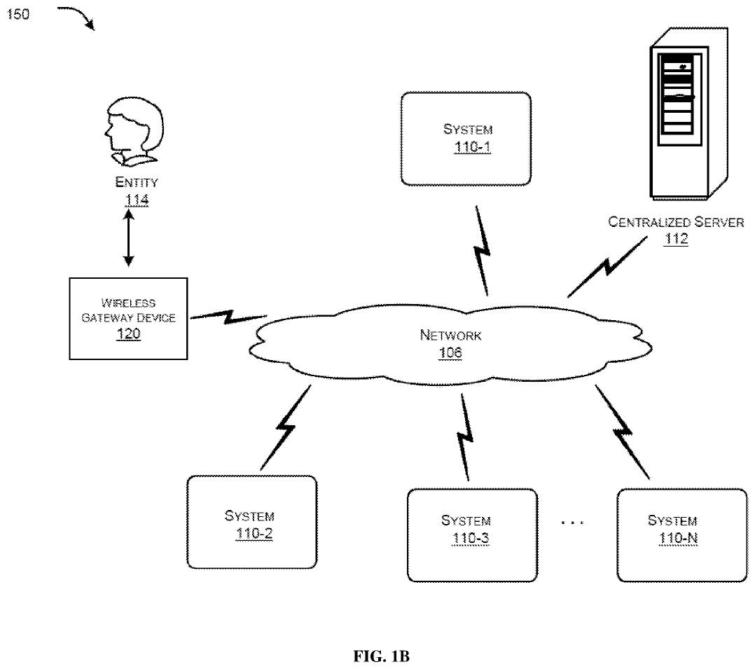

Referring to FIG. 1A that illustrates an exemplary network architecture (100) in which or with which system (110) of the present disclosure can be implemented, in accordance with an embodiment of the present disclosure. As illustrated in FIG. 1, by way of example but not limitation, the exemplary architecture (100) may include a user (102) associated with a user computing device (104) (also referred to as user device (104)), at least a network (106) and at least a centralized server (112). More specifically, the exemplary architecture (100) includes a system (110) for facilitating rack space measurement of a second computing device (108) (also referred to as the data centre (108) hereinafter) of an entity (114). The entity (114) may include a company, an organisation, a university, a lab facility, a business enterprise, a defence facility, or any other secured facility. The data centre (108) may include a plurality of racks and each rack may further include a plurality of levels wherein a predefined amount of data may be stored. The system (110) may further include a wireless network monitoring device (116). The wireless network monitoring device (116) may include a plurality of sensors (not shown in the FIG. 1A) (interchangeably referred to as rack space sensors herein) operatively coupled to a plurality of racks of the data centre (108). A plurality of computing devices may reside in each rack of the plurality of racks in the data centre (108). For example, the plurality of computing devices may include computers, storage devices, servers, routers, networking devices, and the like. In an embodiment, the plurality of sensors may be configured to transmit an infrared signal (IR) to each rack.

In an embodiment, the system (110) may be configured to receive a first set of signals from the wireless sensor monitoring device (116) pertaining to one or more reflected infrared (IR) signals reflected from each rack. The plurality of sensors may transmit an IR signal towards each rack in the data centre. The one or more reflected signals may be obtained after reflection of the IR signal from each rack. The system (110) may then extract a first set of attributes from the first set of signals pertaining to information present in the one or more reflected IR signals and then based on extracted first set of attributes, the system (110) may be configured to determine a number of computing devices residing in the rack. Further, the system (110) may be configured to correlate the number of computing devices with a maximum capacity of computing devices in the rack; and, thereafter determine an amount of space available in the rack.

In an embodiment, the system (110) may further be configured to collate the first set of attributes for the plurality of racks to determine a total space availability in the data centre.

In an embodiment the plurality of sensors may be, but not limited to a plurality of IR sensors placed in a predefined position in each rack. Each IR sensor may include an IR transmitter and an IR receiver. The IR transmitter may be configured to transmit an IR signal to a rack and the IR receiver may be configured to receive a reflected IR signal from the rack. Each IR sensor may be of a predetermined size placed at a predefined distance from each other based on a length of each rack in the data centre. For example, the plurality of sensors may have a size of but not limited to 1000 mm×50 mm×12 mm and a weight of only but not limited to 450 gm.

In an embodiment, the wireless sensor monitoring device further may include a but not limited to a plurality of microcontroller units (MCU) and a plurality of buffer units operatively coupled to each IR sensor.

In an embodiment, a centralized server (112) may be operatively coupled to the system (110). The centralized server may store the first set of signals, the first set of attributes, the second set of attributes, total space availability in the data centre and total number of computing devices in each rack in the data centre. The centralized server (112) may be further associated to a cognitive platform to perform operations based on the data stored in the centralized server.

In an embodiment, the user device (104) may be communicably coupled to the centralized server (112) through the network (106). The user device (104) may enable the user (102) to store, access and monitor the centralized server (112) remotely through the network (106).

Referring to FIG. 1B that illustrates an exemplary network architecture (100) in which or with a wireless network gateway device (120) of the present disclosure can be implemented, in accordance with an embodiment of the present disclosure. The wireless network gateway device (120) (also referred to as wireless gateway device (120) hereinafter) for collecting rack space measurement data of the data centre (108) of the entity (114). The wireless gateway device (120) may include an antenna unit that may be configured to collect the amount of space availability in the rack determined by the system (110). The wireless gateway device (120) may further include a local area network (LAN) operatively coupled to the centralized server (112) through the network (106) and a processor (222). The wireless gateway device (120) may be configured to receive the amount of space availability in the rack determined by the system (110) and then transmit the received the amount of space availability in the rack to the centralized server (112). The wireless gateway device (120) may be of a predetermined size that do not require any rack space. For example, the wireless gateway device may have a size of but not limited to 82 mm×62 mm×28 mm and a weight of only but not limited to 100 gm.

In an embodiment, the data centre (108) and/or the user device (104) may communicate with the system (110) via set of executable instructions residing on any operating system, including but not limited to, Android™, iOS™, Kai OS™ and the like. In an embodiment, data centre (108) and/or the user device (104) may include, but not limited to, any electrical, electronic, electro-mechanical or an equipment or a combination of one or more of the above devices such as mobile phone, smartphone, virtual reality (VR) devices, augmented reality (AR) devices, laptop, a general-purpose computer, desktop, personal digital assistant, tablet computer, mainframe computer, or any other computing device, wherein the computing device may include one or more in-built or externally coupled accessories including, but not limited to, a visual aid device such as camera, audio aid, a microphone, a keyboard, input devices for receiving input from a user such as touch pad, touch enabled screen, electronic pen and the like. It may be appreciated that the computing device (108) and/or the user device (104) may not be restricted to the mentioned devices and various other devices may be used. A smart computing device may be one of the appropriate systems for storing data and other private/sensitive information.

In an exemplary embodiment, a network (106) may include, by way of example but not limitation, at least a portion of one or more networks having one or more nodes that transmit, receive, forward, generate, buffer, store, route, switch, process, or a combination thereof, etc. one or more messages, packets, signals, waves, voltage or current levels, some combination thereof, or so forth. A network may include, by way of example but not limitation, one or more of: a wireless network, a wired network, an internet, an intranet, a public network, a private network, a packet-switched network, a circuit-switched network, an ad hoc network, an infrastructure network, a public-switched telephone network (PSTN), a cable network, a cellular network, a satellite network, a fibre optic network, some combination thereof.

In another exemplary embodiment, the centralized server (112) may include or comprise, by way of example but not limitation, one or more of: a cloud server, a stand-alone server, a server blade, a server rack, a bank of servers, a server farm, hardware supporting a part of a cloud service or system, a home server, hardware running a virtualized server, one or more processors executing code to function as a server, one or more machines performing server-side functionality as described herein, at least a portion of any of the above, some combination thereof.

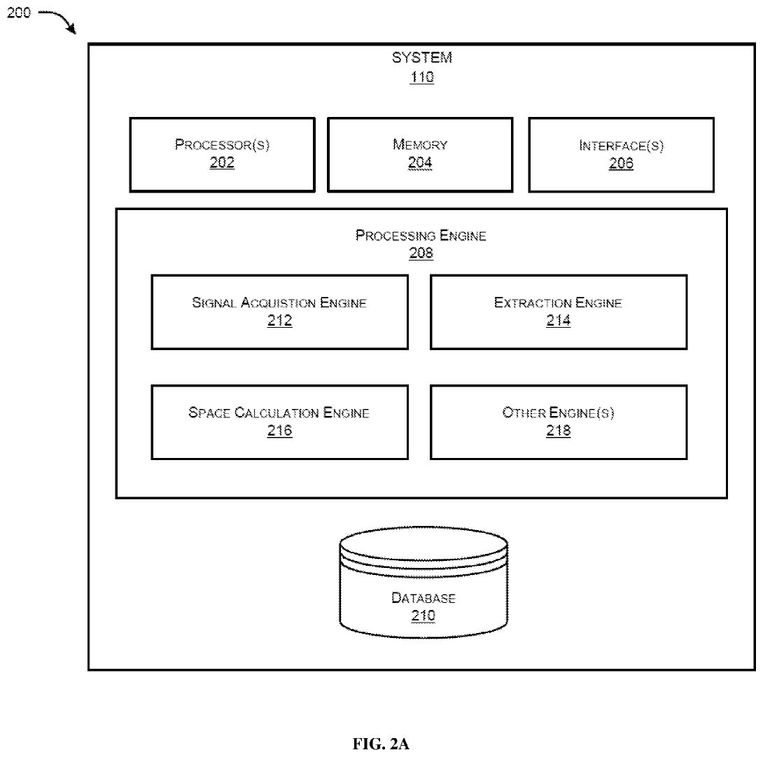

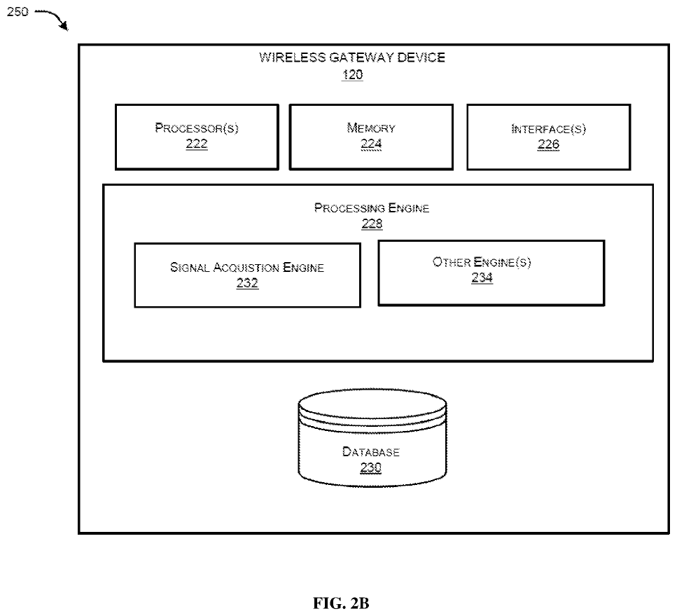

In an embodiment, the system (110) may include one or more processors coupled with a memory, wherein the memory may store instructions which when executed by the one or more processors may cause the system to automatically measure rack space available in a data centre (108). FIG. 2A with reference to FIG. 1A, illustrates an exemplary representation of system (110)) for facilitating measurement of space in a data centre, in accordance with an embodiment of the present disclosure. In an aspect, the system (110) may comprise one or more processor(s) (202). The one or more processor(s) (202) may be implemented as one or more microprocessors, microcomputers, microcontrollers, digital signal processors, central processing units, logic circuitries, and/or any devices that process data based on operational instructions. Among other capabilities, the one or more processor(s) (202) may be configured to fetch and execute computer-readable instructions stored in a memory (204) of the system (110). The memory (204) may be configured to store one or more computer-readable instructions or routines in a non-transitory computer readable storage medium, which may be fetched and executed to create or share data packets over a network service. The memory (204) may comprise any non-transitory storage device including, for example, volatile memory such as RAM, or non-volatile memory such as EPROM, flash memory, and the like.

In an embodiment, the system (110) may include an interface(s) 206. The interface(s) 206 may comprise a variety of interfaces, for example, interfaces for data input and output devices, referred to as I/O devices, storage devices, and the like. The interface(s) 206 may facilitate communication of the system (110). The interface(s) 206 may also provide a communication pathway for one or more components of the system (110). Examples of such components include, but are not limited to, processing engine(s) (208) and a database (210).

The processing engine(s) (208) may be implemented as a combination of hardware and programming (for example, programmable instructions) to implement one or more functionalities of the processing engine(s) (208). In examples described herein, such combinations of hardware and programming may be implemented in several different ways. For example, the programming for the processing engine(s) (208) may be processor executable instructions stored on a non-transitory machine-readable storage medium and the hardware for the processing engine(s) (208) may comprise a processing resource (for example, one or more processors), to execute such instructions. In the present examples, the machine-readable storage medium may store instructions that, when executed by the processing resource, implement the processing engine(s) (208). In such examples, the system (110) may comprise the machine-readable storage medium storing the instructions and the processing resource to execute the instructions, or the machine-readable storage medium may be separate but accessible to the system (110) and the processing resource. In other examples, the processing engine(s) (208) may be implemented by electronic circuitry.

The processing engine (208) may include one or more engines selected from any of a signal acquisition engine (212), an extraction engine (214), a space calculation engine (216), and other engines (218). In an embodiment, the signal acquisition engine (212) of the system (110) can receive a first set of signals from the wireless sensor monitoring device pertaining to one or more reflected infrared signals reflected from each rack of the data centre. An IR signal may be transmitted by the plurality of sensors wherein the one or more reflected signals are obtained after reflection of an IR signal from each said rack. The IR signal may be transmitted by the plurality of sensors.

In an embodiment, the extraction engine (214) may extract a first set of attributes from the first set of signals pertaining to information present in the one or more reflected IR signals and determine, based on extracted first set of attributes, a number of computing devices residing in the said rack.

In an embodiment, the space calculation engine (216) may be configured to correlate the number of computing devices with a maximum capacity of computing devices in the rack; and, thereby determine an amount of space available in the rack.

In an embodiment, the wireless network device (120) may include one or more processors coupled with a memory, wherein the memory may store instructions which when executed by the one or more processors may cause the wireless network device (120) to automatically capture rack space availability in a data centre (108). FIG. 2B with reference to FIG. 1B, illustrates an exemplary representation of the wireless network device (120), in accordance with an embodiment of the present disclosure. In an aspect, the wireless network device (120) may comprise one or more processor(s) (222). The one or more processor(s) (222) may be implemented as one or more microprocessors, microcomputers, microcontrollers, digital signal processors, central processing units, logic circuitries, and/or any devices that process data based on operational instructions. Among other capabilities, the one or more processor(s) (222) may be configured to fetch and execute computer-readable instructions stored in a memory (224) of the wireless network device (120). The memory (224) may be configured to store one or more computer-readable instructions or routines in a non-transitory computer readable storage medium, which may be fetched and executed to create or share data packets over a network service. The memory (224) may comprise any non-transitory storage device including, for example, volatile memory such as RAM, or non-volatile memory such as EPROM, flash memory, and the like.

In an embodiment, the wireless network device (120) may include an interface(s) 226. The interface(s) 226 may comprise a variety of interfaces, for example, interfaces for data input and output devices, referred to as I/O devices, storage devices, and the like. The interface(s) 226 may facilitate communication of the wireless network device (120). The interface(s) 226 may also provide a communication pathway for one or more components of the wireless network device (120). Examples of such components include, but are not limited to, processing engine(s) (228) and a database (230).

The processing engine(s) (228) may be implemented as a combination of hardware and programming (for example, programmable instructions) to implement one or more functionalities of the processing engine(s) (228). In examples described herein, such combinations of hardware and programming may be implemented in several different ways. For example, the programming for the processing engine(s) (228) may be processor executable instructions stored on a non-transitory machine-readable storage medium and the hardware for the processing engine(s) (228) may comprise a processing resource (for example, one or more processors), to execute such instructions. In the present examples, the machine-readable storage medium may store instructions that, when executed by the processing resource, implement the processing engine(s) (228). In such examples, the wireless network device (120) may comprise the machine-readable storage medium storing the instructions and the processing resource to execute the instructions, or the machine-readable storage medium may be separate but accessible to the wireless network device (120) and the processing resource. In other examples, the processing engine(s) (228) may be implemented by electronic circuitry.

The processing engine (228) may include one or more engines selected from any of a signal acquisition engine (232), and other engines (234).

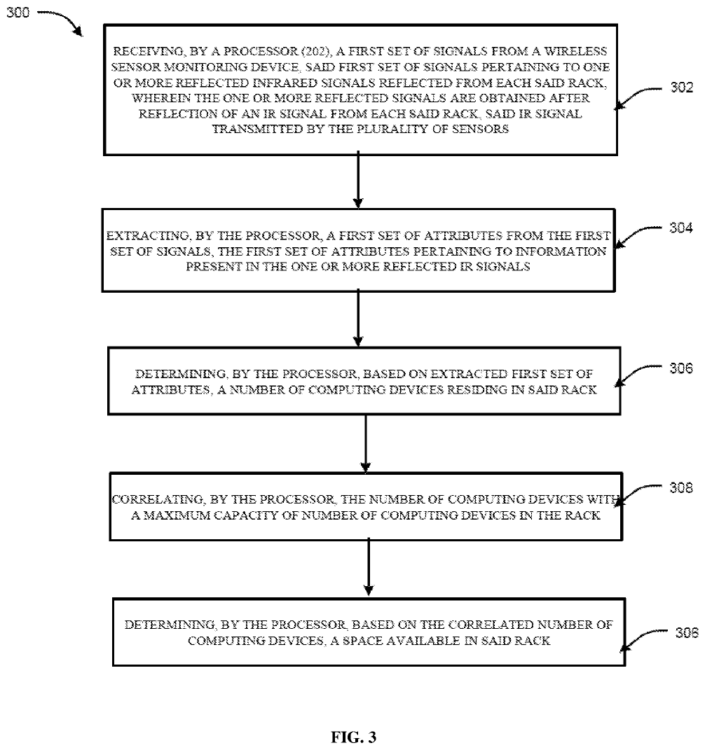

FIG. 3 illustrates exemplary method flow diagram (300) depicting a method for facilitating measurement of rack space in a data centre, in accordance with an embodiment of the present disclosure.

As illustrated, in an aspect the method may facilitate measurement of space availability in each rack of the data centre. The method (300) may include at 302, the step of receiving, by a processor (202), a first set of signals from a wireless sensor monitoring device pertaining to one or more reflected infrared signals reflected from each said rack. The one or more reflected signals may be obtained after reflection of an IR signal from each rack, where the IR signal may be transmitted by the plurality of sensors.

The method may include at 304, the step of extracting, by the processor (202), a first set of attributes from the first set of signals, the first set of attributes pertaining to information present in the one or more reflected IR signals and then at 306, the step of determining, by the processor, based on extracted first set of attributes, a number of computing devices residing in the rack.

Further, at 308, the method may include the step of correlating, by the processor (202), the number of computing devices with a maximum capacity of number of computing devices in the rack; and then at 310, the step of determining, by the processor, based on the correlated number of computing devices, a space available in the rack.

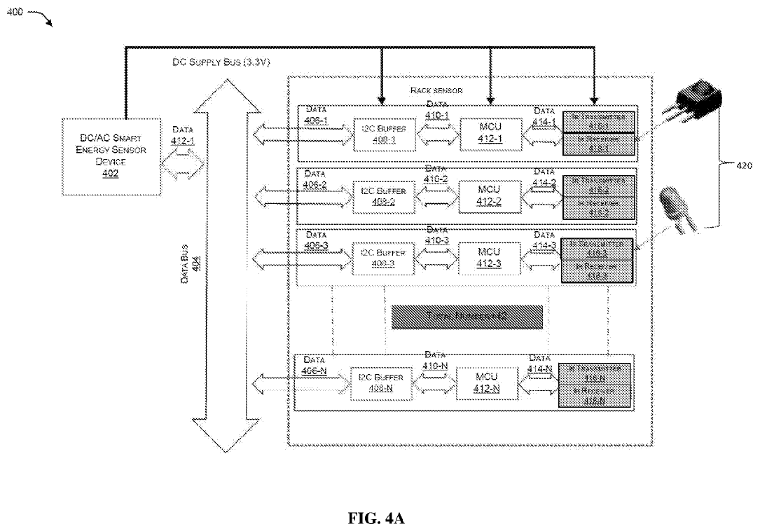

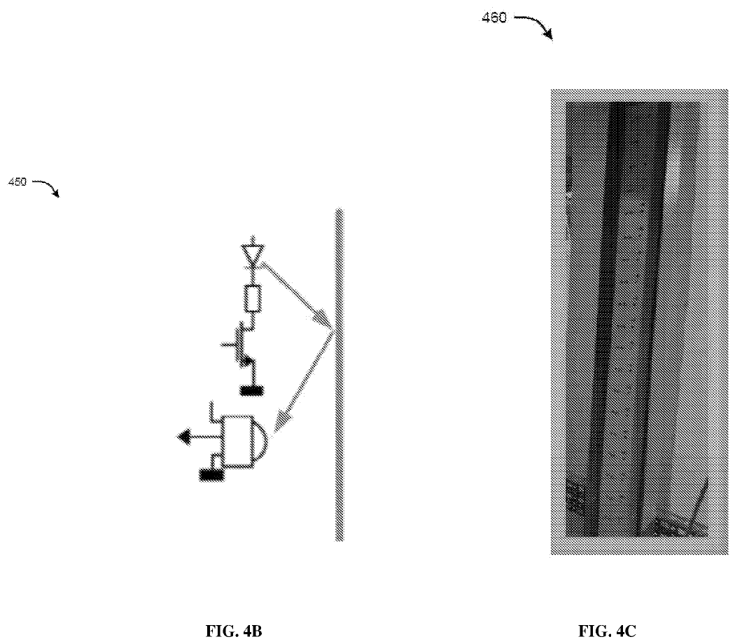

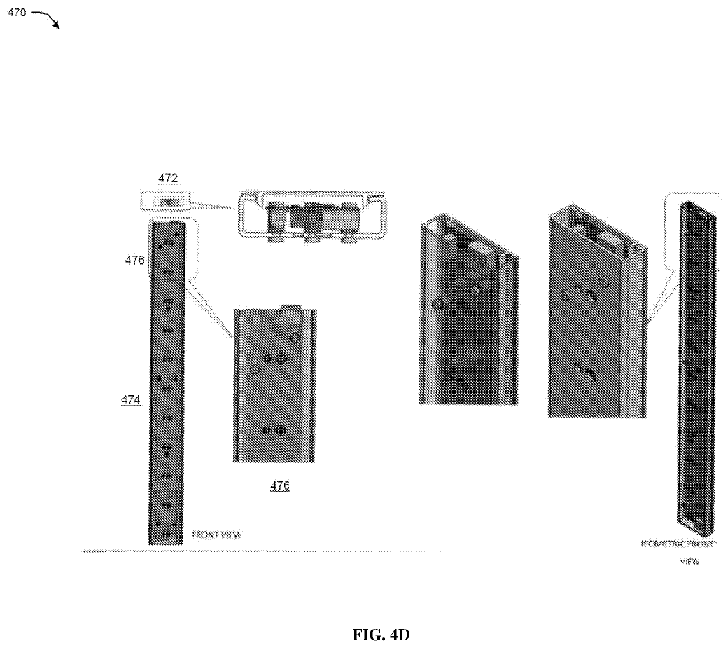

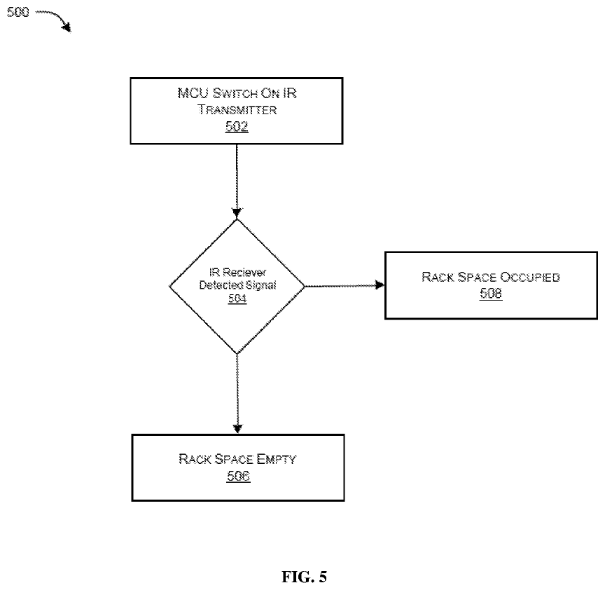

FIGS. 4A-4C illustrate exemplary representations of a functional block diagram (400) of a rack space sensor and its implementation, in accordance with an embodiment of the present disclosure. As illustrated in an aspect, the proposed rack space sensor (420) may include a plurality of infrared (IR) receivers (416-1, 416-2, 416-3 . . . 416-N) (collectively referred to as IR receivers (416) and individually referred to as IR receiver (416)) and also include a plurality of IR transmitters (418-1, 418-2, 418-3 . . . 418-N) (collectively referred to as IR transmitters (418) and individually referred to as IR transmitter (418)). The rack space sensor (400) in a way of example and not as a limitation, may continuously monitor a rack space availability by means of detecting infrared rays (IR) on the IR receiver (416) after reflection of IR waves from a metal material of an installed server at each rack once transmitted from the IR transmitter (418). This rack space sensor may be capable of detecting 42U server space in each rack but not limited to it. The DC supply and communication signals may be provided by an already installed AC and DC Smart Power Sensors (402) in each rack.

In an exemplary embodiment, the processor may be a plurality of Microcontroller Unit (MCU) (412-1, 412-2, 412-3 . . . 412-N) (collectively referred to as MCUs (412) and individually referred to as MCU (412)). The MCU (412) is a low power high performance microcontroller having all the needed data interfaces and peripherals. The MCU (412) is the brain of the design and all the data processing and calculations are done by it. It is the master of the complete design and generating instructions for the other devices in the design. The MCU may be interacting with a master on the energy sensor board to update the status of RACK sensor occupancy.

In an embodiment, the plurality of sensors (also referred to as devices hereinafter) may communicate with a wireless gateway device in the network (106). In an exemplary embodiment, the IR Transmitter (418) may include an infrared emitting diode but not limited to the like. The ON and OFF operations of the IR transmitter (418) may be controlled by the MCU (412).

In an exemplary embodiment, the IR receiver (416) may receive a set of IR pulses. The output of the IR receiver (416) changes state upon detecting an IR pulse. The IR receiver (416) may be further connected with the MCU (412) and utilized in decision making for rack space occupancy. The rack space sensor (400) may further include a plurality of I2C buffers (408) to carry data to the MCUs (412) from a data bus (404). In an exemplary embodiment, the rack space sensor may include at least 42 units but not limited to it.

FIG. 4C illustrates a representation of the rack space sensor. In a way of example and not as a limitation, the Table 1 highlights exemplary features of the rack space sensor.

TABLE 1

| Product Spec | Parameters | |
|---|---|---|
| Sensor Type | IR Based Rack Detection | |
| Average Idle Current | <90 | uA |
| Average Peak Current | 100 | mA |
| Data Communication Interface | I2C | |
| Housing Material | Polycarbonate (PC) | |
| Weight (Approx.) | 450 | gm |
| Dimensions (Approx.) | 1000 mm x 50 mm × 12 mm | |
| Operating Temperature | −10° C. to + 55° C. | |
| Ambient Humidity | ≤95% | RH |
| Water and dust resistance | Indoor Use | |
| Input power supply | 3.3 V from AC/DC Sensor | |
| Electrostatic Discharge | 8 | KV |

| | |
|---|---|
| Mounting Option | 3M Tape |

FIG. 4D illustrates a front view and an iso metric view representation of the rack space sensor in a rack of a data centre. As illustrated in FIG. 4D, a rack space sensor (472) located on a sleeve (474) that is configured to hold a plurality of such rack space sensors (472). The sleeve (474) is placed on a rack of the data centre. A portion (476) of the sleeve (474) having the rack space sensor is shown in an enlarged view (476). It can be clearly seen from the FIG. 4D, that the plurality of rack space sensors are placed in a predefined location at a predefined distance from each other.

FIG. 5 illustrates an exemplary representation (500) of a flow diagram for rack space measurement, in accordance with an embodiment of the present disclosure. As illustrated, the rack space may take decision about rack space availability based on the IR reflections sensed by the IR receiver via the following steps that may include at 502 the step of triggering the IR transmitter by the MCU to switch on the IR transmitter. If at 504, IR reflection is captured by the IR receiver, then at step 508, determining rack space is occupied. If at 504, IR reflection is not captured by the IR receiver, then at step 506, determining rack space is empty. This activity may be repeated for at least 42 units but not limited to it and the frequency of measurement may be configurable.

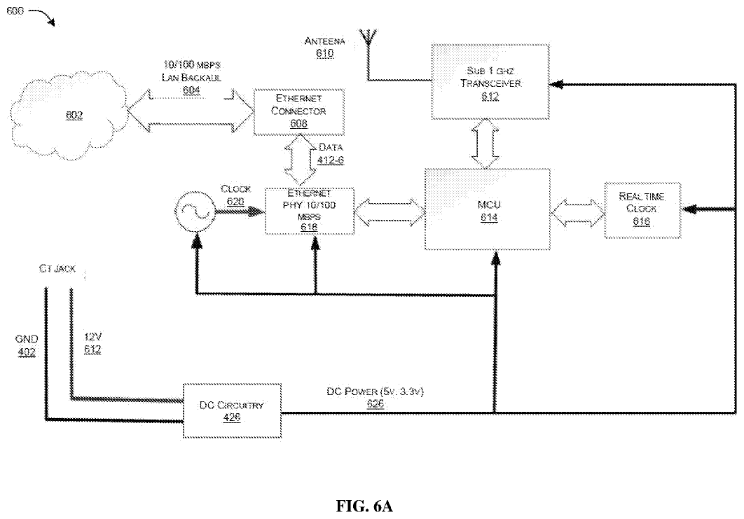

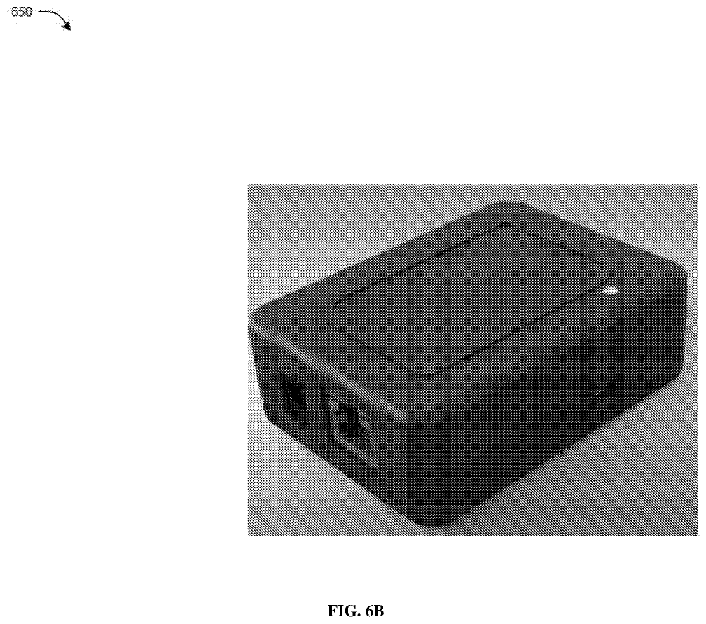

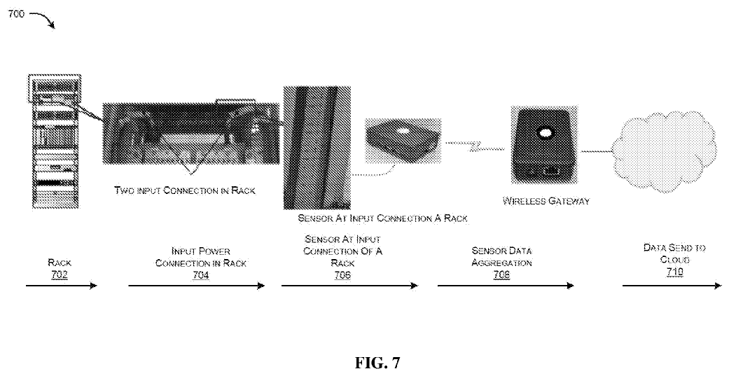

FIG. 6A illustrates an exemplary representation (600) of a Functional Block diagram of wireless network gateway and its implementation, in accordance with an embodiment of the present disclosure. In an aspect the system (110) may include a wireless gateway device (600) that can collect data periodically from at least 100-200 s of sensors (also referred to as the AC/DC Energy measurement devices) deployed in the data centres using sub-GHz RF interface connected in the mesh network. The wireless gateway device (600) may send the collected data to cloud (602) on but not limited to a 10/100 Mbps LAN Ethernet (608) interface for data analytics and post processing for audit purposes. The wireless gateway device (600) may be powered using an AC/DC power adaptor. The wireless gateway device (600) may comprise of at least a 32 bit high end MCU (614) but not limited to it to provide the collected data from the plurality of sensors to 10/100 Mbps LAN interface (604) through a 10/100 Ethernet PHY transceiver (618) followed by magnetic and LAN connector. The wireless gateway device (600) may also comprise of a DC circuitry (624) to provide respective voltages to all other devices and the sub 1 GHz wireless transceiver (612) to collect the Rack space sensor data, an AC/DC sensor data, and Temperature and Humidity sensor data over the air. An antenna (610) may listen to all the data of the plurality of sensors. The Ethernet PHY (618) may be a 10/100 Mbps Ethernet transceiver which is IEEE 802.3u compliant. The Ethernet PHY (618) may interact with the MCU (614) and a cloud server. The data received from the plurality of sensors may be shared to the cloud (602) by the MCU (614) with the help of Ethernet PHY (618). The DC circuit (624) comprising a plurality of DC-DC convertors may be used to generate the required voltage supplies 3.3V for the board.

FIG. 6B illustrates a representation of the wireless gateway device. In a way of example and not as a limitation, the Table 2 highlights exemplary features of the wireless gateway device.

TABLE 2

| Network interface | Ethernet with SNMP | |
|---|---|---|
| Frequency band | Sub 1 GHz | |
| Wireless Protocol Standard | IEEE 802.15.4 | |
| Typical wireless transmission | 10 to 30 meters indoors between | |
| range | any two devices in mesh network | |
| Monitoring units to gateway | Up to 100 Sensor (AC/DC) units per | |
| ratio | gateway | |
| Housing Material | Polycarbonate (PC) | |
| Weight (Approx.) | 100 | gm |
| Dimensions (Approx.) | 82 mm x 62 mm x 28 mm | |
| Operating Temperature | − 10° C. to 55° C. | |
| Ambient Humidity | ≤95% | RH |
| Water & Dust Resistance | Indoor use | |
| External Power Supply | 100 to 240 V AC input; 50/60 Hz | |
| | (12 V DC) output | |
| Firmware updates | Wireless | |
| Antenna | Fully enclosed, fixed configuration | |
| Mounting Options | 3M Tape | |
| Power Consumption | 3 | W |
| Electrostatic Discharge | 8 | KV |

FIG. 7 illustrates an exemplary representation (700) of a flow diagram of data flow from the rack Sensor to cloud, in accordance with an embodiment of the present disclosure. As illustrated, in an aspect, the wireless network gateway device is a wireless device that may interact with at least 50-100 sensor data. The rack space sensor data may be shared with the cloud on LAN interface for data analytics. In an exemplary embodiment, a Sub-1 GHz module may receive data from each rack space sensor in periodic manner, arrange the received data in a pre-defined format and forward data to the cloud on LAN interface. The functional data flow (700) shows how data is transmitted from a rack space sensor (702, 704, 706, 708 and 710) to the cloud while using the rack specie sensor and the wireless gateway device.

In an exemplary embodiment, power may be measured in the plurality of racks in the data centre with the help of at least two types of power sensors—DC Smart Power Sensor (Non-invasive DC Smart PDU) and AC Smart Power Sensor (Non-invasive DC Smart PDU) which continuously measure −48V DC and 230V AC power consumption respectively input supply current and voltage and keeps accumulating the total energy consumed by the load in the device storage. All the energy consumption data is appropriately time stamped using real time clock (RTC) for data analytics purposes in the Cloud. The accumulated energy consumption data may be pushed periodically as per network driven scheduling mechanism. In another exemplary embodiment, the wireless gateway device may collect data periodically from a plurality of rack space sensors deployed in the entity using sub-GHz RF interface connected in a mess network. The device may send the collected data to the cloud on a 10/100 Mbps Ethernet interface but not limited to it for data analytics and post processing for audit purposes. The device will be powered using an AC/DC Power adaptor. The Data collection RF interface between gateway and measurement devices is based on sub-GHz but not limited to it for better coverage and connectivity.

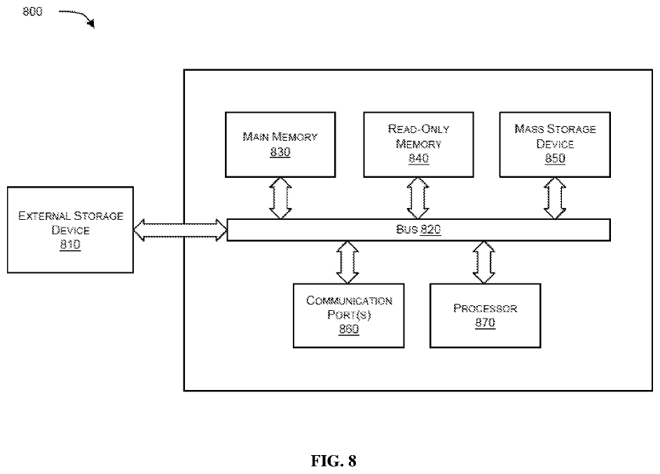

FIG. 8 illustrates an exemplary computer system in which or with which embodiments of the present invention can be utilized in accordance with embodiments of the present disclosure. As shown in FIG. 8, computer system (800) can include an external storage device (810), a bus (820), a main memory (830), a read only memory (840), a mass storage device (870), communication port (860), and a processor (870). A person skilled in the art will appreciate that the computer system may include more than one processor and communication ports. Examples of processor (870) include, but are not limited to, an Intel® Itanium® or Itanium 2 processor(s), or AMD® Opteron® or Athlon MP® processor(s), Motorola® lines of processors, FortiSOC™ system on chip processors or other future processors. Processor (870) may include various modules associated with embodiments of the present invention. Communication port (860 can be any of an RS-232 port for use with a modem-based dialup connection, a 10/100 Ethernet port, a Gigabit or 8 Gigabit port using copper or fiber, a serial port, a parallel port, or other existing or future ports. Communication port (860 may be chosen depending on a network, such a Local Area Network (LAN), Wide Area Network (WAN), or any network to which computer system connects. Memory 830 can be Random Access Memory (RAM), or any other dynamic storage device commonly known in the art. Read-only memory (840) can be any static storage device(s) e.g., but not limited to, a Programmable Read Only Memory (PROM) chips for storing static information e.g., start-up or BIOS instructions for processor (870). Mass storage (850) may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces), e.g. those available from Seagate (e.g., the Seagate Barracuda 782 family) or Hitachi (e.g., the Hitachi Deskstar 7K800), one or more optical discs, Redundant Array of Independent Disks (RAID) storage, e.g. an array of disks (e.g., SATA arrays), available from various vendors including Dot Hill Systems Corp., LaCie, Nexsan Technologies, Inc. and Enhance Technology, Inc.

Bus (820) communicatively couple processor(s) (870) with the other memory, storage and communication blocks. Bus (820) can be, e.g., a Peripheral Component Interconnect (PCI)/PCI Extended (PCI-X) bus, Small Computer System Interface (SCSI), USB or the like, for connecting expansion cards, drives and other subsystems as well as other buses, such a front side bus (FSB), which connects processor (870) to software system.

Optionally, operator and administrative interfaces, e.g., a display, keyboard, joystick and a cursor control device, may also be coupled to bus (820) to support direct operator interaction with a computer system. Other operator and administrative interfaces can be provided through network connections connected through communication port (860). The external storage device (88) can be any kind of external hard-drives, floppy drives, IOMEGA® Zip Drives, Compact Disc-Read Only Memory (CD-ROM), Compact Disc-Re-Writable (CD-RW), Digital Video Disk-Read Only Memory (DVD-ROM). Components described above are meant only to exemplify various possibilities. In no way should the aforementioned exemplary computer system limit the scope of the present disclosure.

The present disclosure provides a plurality of sensors that uses zero rack space because the plurality of sensors are very small and, hence no rack space is required to install these devices. Moreover, the small size sensors are very easy to handle and can be easily integrated with the antenna without disturbing the property of antenna. A cost-effective solution as compared to the available solutions is provided wherein the cost is approximately 95% less than its peers. Furthermore, the Rack Space Sensor, the power sensors and environment sensor will be connected to the same wireless gateway and thus one gateway can support connectivity up to at least 100 sensors but not limited to it. The present invention also provides a zero service down time as no service downtime is required to install the sensors.

While considerable emphasis has been placed herein on the preferred embodiments, it will be appreciated that many embodiments can be made and that many changes can be made in the preferred embodiments without departing from the principles of the invention. These and other changes in the preferred embodiments of the invention will be apparent to those skilled in the art from the disclosure herein, whereby it is to be distinctly understood that the foregoing descriptive matter to be implemented merely as illustrative of the invention and not as limitation.

### Advantages of the Present Disclosure

The present disclosure provides a system and a method that uses zero rack space as devices are very small, hence no rack space is required to install these devices.

The present disclosure provides a system and a method facilitates use of small size devices which are very easy to handle and easy to integrate with the antenna without disturbing the property of antenna

The present disclosure provides a cost-effective solution as compared to the available solutions where the cost is approximately 95% less than its peers.

The present disclosure provides a wireless gateway device that can support connectivity up to 150 sensors or more.

The present disclosure provides a system and a method that has zero service down time i.e., no service downtime required to install the sensors.

We claim:

1. A system (110) for facilitating rack space measurement of a data centre (108) of an entity (114), said system comprises:
a wireless sensor monitoring device, said wireless sensor monitoring device (116) comprising a plurality of sensors (420), said plurality of sensors (420) operatively coupled to a plurality of racks of the data centre (108), said plurality of racks having a plurality of computing devices residing in each rack, and wherein the plurality of sensors (420) is configured to transmit an infrared signal (IR) to each rack;
a processor (202), said processor operatively coupled to the wireless sensor monitoring device through a network (106), said processor (202) coupled with a memory (204), wherein said memory (204) stores instructions which when executed by the processor (202) causes the processor (202) to:
receive a first set of signals from the wireless sensor monitoring device, said first set of signals pertaining to one or more reflected infrared signals reflected from each said rack, wherein the one or more reflected signals are obtained after reflection of an IR signal from each said rack, said IR signal transmitted by the plurality of sensors;
extract a first set of attributes from the first set of signals, the first set of attributes pertaining to information present in the one or more reflected IR signals;
determine, based on extracted first set of attributes, a number of computing devices residing in said rack;
correlate the number of computing devices with a maximum capacity of computing devices in the rack; and,
determine based on the correlated number of computing devices, an amount of space available in said rack.

2. The system as claimed in claim 1, wherein the processor (202) collates the first set of attributes for the plurality of racks to determine a total space availability in the data centre.

3. The system as claimed in claim 1, wherein the plurality of sensors (420) is a plurality of JR sensors placed in a predefined position in each rack, wherein each IR sensor comprises an JR transmitter (418) and an JR receiver (416), wherein the IR transmitter (418) is configured to transmit an IR signal to a rack and the IR receiver (416) is configured to receive a reflected IR signal from the rack.

4. The system as claimed in claim 4, wherein each IR sensor is of a predetermined size placed at a predefined distance from each other in based on a length of each rack in the data centre.

5. The system as claimed in claim 1, wherein the wireless sensor monitoring device further comprises a plurality of microcontroller units (MCU) (412) and a plurality of buffer units (408) operatively coupled to each IR sensor.

6. The system as claimed in claim 1, wherein a centralized server (112) operatively coupled to the system (110) stores the first set of signals, the first set of attributes, the second set of attributes, total space availability in the data centre and total number of computing devices in each rack in the data centre.

7. The system as claimed in claim 6, wherein a user device (104) is communicably coupled to the centralized server (112) through the network (106), wherein the user device (104) enables a user to store, access and monitor the centralized server (112) remotely through the network (106).

8. A wireless gateway device (120) for collecting rack space measurement data of a data centre (108) of an entity (114), said device comprises:
an antenna unit (618), said antenna unit (618) collects an amount of space availability in the rack determined by the system (110);
a local area network (LAN) (618), said LAN (618) operatively coupled to a centralized server (112) through a network (106);
a processor (222), said processor coupled with a memory (224), wherein said memory stores instructions which when executed by the processor causes the processor (222) to:
receive the amount of space availability in the rack determined by the system (110);
transmit the received the amount of space availability in the rack to the centralized server (112).

9. The device as claimed in claim 8, wherein the wireless gateway device (120) is of a predetermined size that do not require any rack space.

10. The device as claimed in claim 8, wherein the centralized server (112) stores the first set of signals, the first set of attributes, the second set of attributes, total space availability in the data centre and total number of computing devices in each rack in the data centre.

11. The device as claimed in claim 10, wherein a user device (104) is communicably coupled to the centralized server (112) through the network (106), wherein the user device (104) enables a user (102) to store, access and monitor the centralized server (112) remotely through the network (106).

12. The device as claimed in claim 8, wherein the device is further configured to manage a plurality of systems (110).

13. A method for facilitating rack space measurement of a data centre (108) of an entity (114), said method comprises:
receiving, by a processor (202), a first set of signals from a wireless sensor monitoring device, said first set of signals pertaining to one or more reflected infrared signals reflected from each said rack, wherein the one or more reflected signals are obtained after reflection of an IR signal from each said rack, said IR signal transmitted by the plurality of sensors,
wherein said wireless sensor monitoring device (116) comprising a plurality of sensors (420), said plurality of sensors (420) operatively coupled to a plurality of racks of the data centre (108), said plurality of racks having a plurality of computing devices residing in each rack, and wherein the plurality of sensors (420) is configured to transmit an infrared signal (IR) to each rack,
wherein said wireless sensor monitoring device (116) is operatively coupled to the processor (202), said processor (202) coupled with a memory (204), wherein said memory (204) stores instructions that are executed by the processor (202);
extracting, by the processor, a first set of attributes from the first set of signals, the first set of attributes pertaining to information present in the one or more reflected IR signals;
determining, by the processor, based on extracted first set of attributes, a number of computing devices residing in said rack;
correlating, by the processor, the number of computing devices with a maximum capacity of number of computing devices in the rack; and,
determining, by the processor, based on the correlated number of computing devices, an amount of space available in said rack.

14. The method as claimed in claim 13, wherein the method further comprises:
collating, by the processor, the first set of attributes for the plurality of racks to determine a total space availability in the data centre.

15. The method as claimed in claim 13, wherein the plurality of sensors (420) is a plurality of IR sensors placed in a predefined position in each rack, wherein each IR sensor comprises an IR transmitter (418) and an IR receiver (416), wherein the IR transmitter (418) is configured to transmit an IR signal to a rack and the IR receiver (416) is configured to receive a reflected IR signal from the rack.

16. The method as claimed in claim 15, wherein each IR sensor (420) is of a predetermined size placed at a predefined distance from each other in based on a length of each rack in the data centre.

17. The method as claimed in claim 13, wherein the wireless sensor monitoring device further comprises a plurality of microcontroller units (MCU) (412) and a plurality of buffer units (408) operatively coupled to each IR sensor.

18. The method as claimed in claim 17, wherein the wireless monitoring device is of a predetermined size that do not require any rack space.

19. The method as claimed in claim 13, wherein a centralized server (112) operatively coupled to the wireless monitoring device stores the first set of signals, the first set of attributes, the second set of attributes, total space availability in the data centre and total number of computing devices in each rack in the data centre.

20. The method as claimed in claim 19, wherein a user device (104) is communicably coupled to the centralized server (112) through a network (106), wherein the user device (104) enables a user to store, access and monitor the centralized server (112) remotely through the network (106).
